(19) United States
(12) Patent Application Publication
(10) Pub. No.: US 2025/0382693 A1
(43) Pub. Date: Dec. 18, 2025

(54) MASK MODULE, SUBSTRATE CARRIER, SUBSTRATE PROCESSING SYSTEM, AND METHOD OF PROCESSING A SUBSTRATE

(71) Applicant: Applied Materials, Inc., Santa Clara, CA (US)

(72) Inventors: Sang Cheol LEE, Santa Clara, CA (US); Daniel HWANG, Santa Clara, CA (US); Gyeong Ho JO, Santa Clara, CA (US); Myung Sun LEE, Santa Clara, CA (US); Young Do KIM, Santa Clara, CA (US); Tommaso VERCESI, Aschaffenburg (DE); Kwan Sung KIM, San Jose, CA (US); Yu-Hsin LIN, Zhubei City (TW)

(21) Appl. No.: 18/875,805

(22) PCT Filed: Oct. 26, 2022
(86) PCT No.: PCT/IB2022/060280

§ 371 Date: Dec. 17, 2024

Related U.S. Application Data
(60) Provisional application No. 63/357,962, filed on Jul. 1, 2022.

(51) Int. Cl. C23C 14/04; C23C 14/24; C23C 14/50; H10K 71/16; H10K 71/70

(52) U.S. Cl. CPC C23C 14/042; C23C 14/24; C23C 14/50; H10K 71/166; H10K 71/70

(57) ABSTRACT

A mask module configured to be coupled to a substrate carrier is described. The mask module includes a body; a mask coupled to the body, the mask having one or more first openings; a movable shutter, the movable shutter having one or more second openings; and an actuator coupled to the movable shutter. The actuator is configured to move the one or more second openings to align at least one opening of the one or more second openings over at least one opening of the one or more first openings.

### TECHNICAL FIELD

Embodiments of the present disclosure relate to a generation of test structures or test elements (e.g. test element groups) in a substrate processing system, particularly an in-line substrate processing system. Further, embodiments of the present disclosure relate to a system and a method to evaporate an OLED layer stack. Embodiments of the present disclosure particularly relate to a mask module, a substrate carrier, a substrate processing system, a method of processing a substrate, e.g. in an in-line substrate processing system, and a method of manufacturing a layer stack of a display on a large area substrate.

### BACKGROUND

Organic light-emitting diodes (OLED) are a special type of light-emitting diode in which the emissive layer includes a thin film of certain organic compounds. OLEDs are used in the manufacture of television screens, computer monitors, mobile phones, other hand-held devices, etc. for displaying information. OLEDs can also be used for general space illumination. The range of colors and brightness possible with OLED displays is greater than that of traditional LCD displays because OLED material emits light directly. The energy consumption of OLED displays is considerably less than that of traditional LCD displays.

Furthermore, the fact that OLEDs can be manufactured onto flexible substrates allows for still further applications. An OLED display may include, for example, layers of organic material situated between two electrodes, for example electrodes made of a metallic material. The OLED is typically placed between two glass panels, and the edges of the glass panels are sealed to encapsulate the OLED therein. Alternatively, the OLED can be encapsulated with thin-film technology, e.g. with a barrier film.

For manufacturing OLED devices but also for manufacturing other devices, a plurality of material layers is deposited on a substrate. The plurality of material layers can be deposited by a corresponding plurality of deposition sources, e.g. evaporation sources. Deposition sources may deposit different materials, such that the deposition sources have individual source conditions, e.g. for optimized substrate processing. The individual source conditions are beneficially monitored. For example, layer thickness or layer uniformity of an individual source is beneficially monitored. In particular, operation-condition monitoring can be provided during manufacturing under production conditions.

In light of the above, it is beneficial to provide apparatuses and methods that allow for individual monitoring of process conditions for different layers deposited on a substrate.

### SUMMARY

In light of the above, a mask module, a substrate carrier, a substrate-processing system, and methods of processing a substrate are provided, particularly in an in-line deposition system. Further aspects, embodiments, features and details can be derived from the dependent claims, the drawings and the specification.

According to an embodiment, a mask module configured to be coupled to a substrate carrier is provided. The mask module includes a body; a mask coupled to the body, the mask having one or more first openings; a movable shutter, the movable shutter having one or more second openings; and an actuator coupled to the movable shutter. According to some embodiments, which can be combined with other embodiments described herein, the actuator is configured to move at least a portion of the mask module relative to the carrier. The actuator is configured to move the one or more second openings to align at least one opening of the one or more second openings over at least one opening of the one or more first openings.

According to an embodiment, a mask module configured to be coupled to a substrate carrier for carrying a substrate is provided. The mask module includes a body; a movable shutter, the movable shutter comprising one or more second openings; one or more spacers arranged on a side of the movable shutter and configured to be provided between the movable shutter and the substrate; and an actuator coupled to the movable shutter and configured to move the one or more second openings to align at least one opening of the one or more second openings over a test element on a substrate.

According to an embodiment, a substrate carrier is provided. The substrate carrier includes a carrier body; an electrostatic chuck; a substrate receiving surface, particularly provided by the carrier body and/or the electrostatic chuck; and a mask module. The mask module includes a body; a mask coupled to the body, the mask having one or more first openings to be positioned over the substrate receiving surface; and a movable shutter, the movable shutter having one or more second openings, wherein the mask is provided between the movable shutter and the substrate receiving surface. The mask module further includes an actuator coupled to the movable shutter and configured to move the one or more second openings relative to the one or more first openings.

According to an embodiment, a mask module configured to be coupled to a substrate carrier for carrying a substrate is provided. The mask module includes a body; a movable shutter, the movable shutter comprising one or more second openings; one or more spacers arranged on a side of the movable shutter and configured to be provided between the movable shutter and the substrate; and an actuator coupled to the movable shutter and configured to move the one or more second openings to align at least one opening of the one or more second openings over a test element on a substrate.

According to an embodiment, a substrate processing system is provided. The substrate processing system includes one or more vacuum chambers; a plurality of deposition sources provided in the one or more vacuum chambers; a substrate transportation track configured to move a substrate of a plurality of substrates subsequently past the plurality of deposition source in order to deposit layers of different materials on the substrate; and one or more substrate carriers according to any of the embodiments described herein.

According to an embodiment, a method of processing a substrate is provided. The method includes depositing a first material layer on the substrate, the first material being deposited in a device region and a first test region of a plurality of test regions, wherein the first material is deposited in the first test region through one or more first openings in a mask and through one or more second openings in a movable shutter; moving the one or more second openings relative to the one or more first openings; and depositing a second material layer on the substrate, the second material being deposited in the device region and a second test region of the plurality of test regions, wherein the second material is deposited in the second test region through one or more first openings in the mask and through one or more second openings in the movable shutter.

### BRIEF DESCRIPTION OF THE DRAWINGS

So that the manner in which the above recited features of the present disclosure can be understood in detail, a more particular description of the disclosure, briefly summarized above, may be had by reference to embodiments. The accompanying drawings relate to embodiments and are described in the following:

FIG. 1 shows a schematic view of a portion of a substrate carrier and a mask module according to embodiments of the present disclosure;

FIG. 2 shows a schematic view of a substrate carrier having one or more mask modules according to embodiments of the present disclosure;

FIG. 3A shows a schematic view of a portion of a substrate carrier and a mask module according to embodiments of the present disclosure;

FIG. 3B shows a schematic view of a portion of a substrate carrier and a mask module according to embodiments of the present disclosure;

FIG. 4A shows a schematic view of a shutter, a mask and an overlay arrangement of the shutter and the mask;

FIG. 4B shows a schematic view of a shutter, a mask and an overlay arrangement of the shutter and the mask;

FIG. 5A shows a schematic view of a shutter and a mask according to embodiments of the present disclosure;

FIG. 5B shows a schematic view of a shutter having a spacer to form a mask module according to embodiments of the present disclosure;

FIG. 6 shows a schematic view of a substrate processing system according to embodiments of the present disclosure; and

FIG. 7 shows a flowchart illustrating a method of processing a substrate according to embodiments described herein.

### DETAILED DESCRIPTION OF EMBODIMENTS

Reference will now be made in detail to the various embodiments, one or more examples of which are illustrated in the figures. Within the following description of the drawings, the same reference numbers refer to the same components. Generally, only the differences with respect to individual embodiments are described. Each example is provided by way of explanation and is not meant as a limitation of the disclosure. Further, features illustrated or described as part of one embodiment can be used on or in conjunction with other embodiments to yield yet a further embodiment. It is intended that the description includes such modifications and variations.

A process to manufacture OLED displays can include thermal evaporation of organic materials and deposition of organic materials on a substrate in a high vacuum. Particularly a plurality of materials can be deposited to generate a plurality of material layers on a substrate. Measurement of properties of the individual material layers, for example, layer thickness measurement of individual layers, is beneficial. Accordingly, process conditions for depositing the individual layers can be monitored.

Embodiments of the present disclosure relate to a mask module, a substrate carrier, substrate processing systems, and a method of processing a substrate. Particularly, a substrate can be processed in an in-line deposition system for generating a plurality of layers on the substrate, wherein, for example, a plurality of substrates is subsequently processed, particularly coated with a layer stack.

Embodiments of the present disclosure allow for masking portions of the substrate, particularly portions of the substrate on which no devices are manufactured. The masking can be provided at different substrate locations to have, for example, only one material at a specific substrate location. This allows for process control of the deposition of the specific one material.

The mask module and substrate carriers carrying at least one mask module according to embodiments of the present disclosure may be utilized for vertical substrate processing systems and for horizontal substrate processing systems.

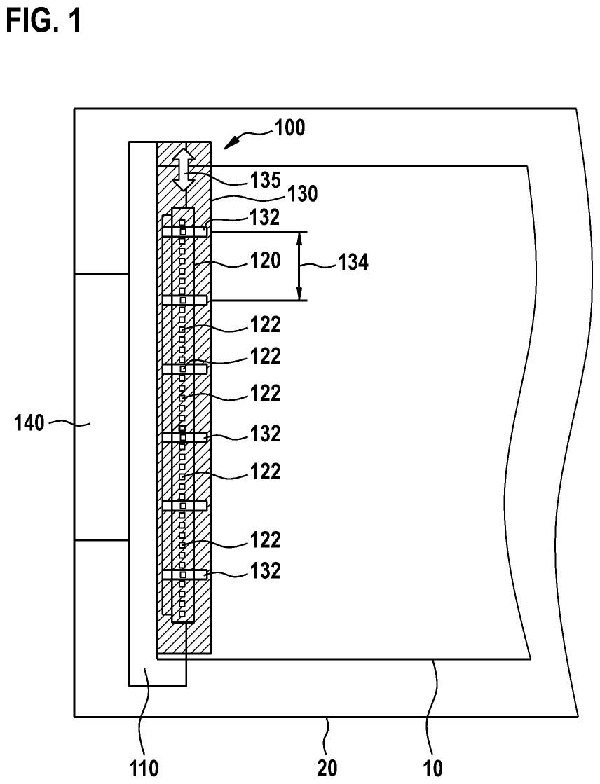

FIG. 1 shows a carrier 20. A substrate 10 is supported by the carrier 20. Further, a mask module 100 according to embodiments of the present disclosure is provided. The mask module 100 includes a body 110, a mask 120, and a shutter 130. Further, an actuator 140 or drive unit can be provided. The actuator 140 is configured to move the shutter 130 as indicated by arrow 135.

The mask 120 and the shutter 130 are provided at a side region of the substrate 10, particularly a region in which no devices are to be manufactured on the substrate during production.

The mask 120 includes a plurality of first openings 122. A first opening 122 provides a structure for a test element. A plurality of test elements can be utilized to form a test element group, i.e. a group of test elements which are distributed over the substrate. Distribution of test elements over the substrates allow for measuring or monitoring uniformity of material deposition. According to some embodiments, which can be combined with other embodiments described herein, one or more first openings in the mask can define a plurality of test elements or a test element group. Particularly, test elements distributed over the substrate, for example, along a line on the substrate, can define a test element group

The mask is coupled to the body 110 of the mask module 100. The one or more first openings 122 in the mask provide positions at which different materials can be deposited for testing, measuring, and/or monitoring. The shutter 130 includes one or more second openings 132. For depositing material on the substrate at a specific test element, a second opening 132 is aligned with a first opening 122. In the example shown in FIG. 1, a deposition source would be provided above the paper plane, i.e. above the substrate 10. The substrate, the mask 120, the shutter 130, and the evaporation source would be provided in this order starting from the paper plane. Accordingly, according to some embodiments, which can be combined with other embodiments described herein, the mask 120 can be provided between the substrate 10 and the shutter 130. It is to be understood that for a vertical substrate orientation, for example, during vertical substrate processing, the elements would be next to each other. The alignment of a second opening 132 and a first openings 122 allows for deposition of material through the two openings onto the substrate.

According to some embodiments, which can be combined with other embodiments described herein, the mask includes a mask stick or a mask stripe. The mask can have a first dimension of 40 mm or less and a second dimension of 500 mm or more. According to some embodiments, which can be combined with other embodiments described herein, the mask has a first dimension and a second dimension, the second dimension being at least 6 times larger than the first dimension. Particularly, as shown in FIG. 1, the mask module, or the mask and the shutter, are provided along the side of the substrate 10 and may extend along the length of the side of the substrate. The mask module is provided outside the substrate area which is intended for device manufacturing on the substrate.

As shown in FIG. 1, the plurality of first openings 122 may be equally spaced by a first distance. The plurality of first openings can be arranged in a line or more be arranged to form a line. Further, the plurality of second openings 132 may be spaced by a second distance 134, which is different from the first distance. FIG. 1 exemplarily shows six second openings spaced by the second distance 134. The plurality of second openings allows for simultaneous deposition of a material on the substrate, particularly at different locations. The different locations may be arranged along a side of the substrate. The different substrate locations may serve to monitor or measure the uniformity of material deposition, e.g. along a first substrate dimension, such as in a vertical direction.

By moving the shutter 130 having the one or more second openings 132 as indicated by arrow 135, the one or more second openings can be aligned with different first openings (test elements) or a different plurality of first openings forming a test element group. Material deposited at a previous test element or previous test element group is covered by the shutter. The material deposition can be individualized on the substrate during production.

According to some embodiments, which can be combined with other embodiments described herein, the shutter, such as a thin shutter, can be moved (e.g. up and down in FIG. 1) by the actuator 140 or driving unit to be located at one or more of the test element cutouts in the mask, i.e. one or more of the first openings. For example, the movable shutter is movable parallel to a substrate-receiving surface of the substrate carrier on which the substrate 10 is to be supported. According to some embodiments, which can be combined with other embodiments described herein, the shutter 130 has a length such that it is long enough to cover the mask, i.e. the mask stick, for reducing or avoiding material deposition on the mask. According to some embodiments, which can be combined with other embodiments described herein, the shutter has a length which is greater than the length of the mask. According to some embodiments, which can be combined with other embodiments described herein, the shutter has a width which is greater than the width of the mask.

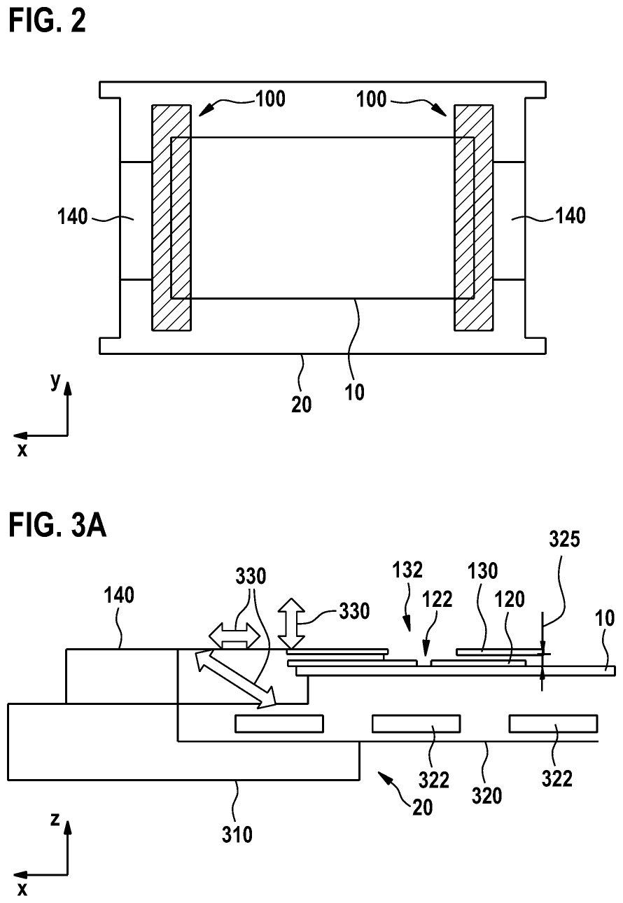

FIG. 2 shows a carrier 20. The carrier 20 is shown in a side view wherein, as an optional implementation, a vertical carrier orientation is described. The carrier 20 supports the substrate 10. A first mask module 100 is shown on one side of the carrier, e.g. the left-hand side of the carrier. The first mask module may include an actuator 140 or drive unit. According to some embodiments, which can be combined with other embodiments described herein, a second mask module 100 or a further mask module can be provided at the second side of the carrier. For example, the second side can be a side opposite the first side. According to some embodiments, which can be combined with other embodiments described herein, a substrate carrier 20 may include one or more mask modules according to embodiments of the present disclosure. According to some embodiments, which can be combined with other embodiments described herein, the mask has a first dimension which is 20% or less, particularly 10% or less, of the size of the substrate receiving surface in the same direction. For example, the mask 120 may only cover an area amounting to 10% or less of the substrate during deposition, particularly an edge region of the substrate that can be used for test and/or monitoring purposes.

According to some embodiments, which can be combined with other embodiments described herein, the substrate carrier may further include one or more magnetic elements configured for levitating and/or driving the carrier, e.g. with a magnetic levitation system, wherein the one more magnetic elements are selected from the group consisting of: a magnetic material, a permanent magnet, an electromagnet, or a combination thereof.

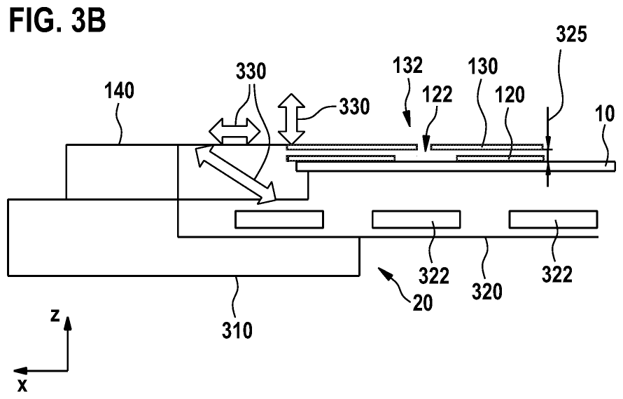

According to some embodiments, a mask module configured to be coupled to a substrate carrier is provided. The mask module includes a body; a mask coupled to the body, the mask comprising one or more first openings; a movable shutter, the movable shutter comprising one or more second openings; and an actuator coupled to the movable shutter and configured to move the one or more second openings of the shutter to align at least one opening of the one or more second openings over at least one opening of the one or more first openings. In particular, the movable shutter is arranged above the mask. According to some embodiments, which can be combined with other embodiments described herein, the movable shutter is arranged adjacent the mask and optionally spaced from the substrate by a gap (see gap 325 in FIGS. 3A and 3B). For example, the shutter may be arranged over the mask at a small distance, e.g. 1 cm or less or 1 mm or less and/or may be arranged over the substrate at a small distance, e.g. 1 cm or less or 1 mm or less.

According to an embodiment, a substrate carrier is provided. The substrate carrier includes a carrier body, an electrostatic chuck, and a mask module. The carrier body may provide a substrate receiving surface at which a substrate 10 can be carried, particularly using an electrostatic chuck of the substrate carrier. The mask module includes a body; a mask coupled to the body, the mask including one or more first openings to be positioned over the substrate receiving surface; a movable shutter, the movable shutter comprising one or more second openings, wherein the mask is provided between the movable shutter and the substrate receiving surface; and an actuator coupled to the movable shutter and configured to move the one or more second openings relative to the one or more first openings, particularly configured to move the shutter relative to the mask.

As shown in FIG. 2, the shutter of the mask module may move in y-direction for selecting test elements or test element groups during the processing of a layer stack.

According to some embodiments, which can be combined with other embodiments described herein, the mask module is detachable from and attachable to the substrate carrier. Having the mask module detachable and attachable to the substrate carrier allows a transformation of a “normal substrate carrier” to a “smart carrier”. A “smart carrier” as referred to herein allows the flexible exposure of test elements or test element groups on the substrate, e.g. by moving the shutter relative to the mask. The switching between test elements or test element groups can be provided during the manufacture of a layer stack, particularly in a substrate processing system. Switching between test elements or test element groups can be provided without removing the substrate carrier from the vacuum chamber or a plurality of vacuum chambers of the substrate processing system.

A “smart carrier” can be provided for an in-line substrate processing system. Thickness tooling, e.g. by optimizing or improving source conditions, and monitoring, particularly under mass production, is enabled. For example, monitoring may indicate material plume direction and/or nozzle direction of a deposition source. A mask module, e.g. a detachable mask module, providing test elements or test element groups with a mask and a shutter, can be provided. For example, one or two mask modules can be provided at different sides of the substrate carrier, for example, at a left and/or a right side of the substrate carrier. Particularly, the mask module can be provided at the substrate carrier in an area or region in which no device manufacturing on a substrate occurs.

FIGS. 3A and 3B show a carrier 20 and the mask module coupled to the carrier 20. The carrier includes a carrier body 310 and an electrostatic chuck 320. For example, the electrostatic chuck includes one or more electrodes 322. The one or more electrodes 322 can be biased to generate an attractive force on the substrate 10. According to some embodiments, which can be combined with other embodiments described herein, the one or more electrodes can be embedded in a dielectric material of the carrier body. The mask module includes the mask 120 having the one or more first openings 122 and the shutter 130 having the one or more second openings 132. Further, the mask module includes a body and the actuator 140. The mask 120 may be attached to the body of the mask module. According to some embodiments, which can be combined with other embodiments described herein, the mask 120 can be attracted toward the carrier by the electrostatic chuck, particularly by electrostatic forces provided by the electrostatic chuck. For example, the mask 120 can be attracted toward the substrate 10 so as to contact the substrate during material deposition through one or more first openings 122. Additionally or alternatively, the body of the mask module can be attached to the carrier by the electrostatic chuck. According to some embodiments, which can be combined with other embodiments described herein, the body of the mask module includes a material configured to be attracted by the electrostatic force of the electrostatic chuck.

As shown in FIG. 3A, the second opening 132 can be larger than the first opening. This may, however, result in material being deposited on the mask 120. According to some embodiments, which can be combined with other embodiments described herein, and as illustrated in FIG. 3B, one or more of the second openings 132, particularly each of the second openings 132, can be smaller than one or more of the first openings 122, particularly each of the first openings 122. Material deposition on the mask 120 can be reduced or avoided. Thus, no material is deposited between the mask 120 and the shutter 130, e.g. in a gap between the mask 120 and the shutter 130. Particle generation, particularly upon movement of the shutter 130 to align a second opening with a different first opening, can be reduced or avoided.

According to some embodiments, which can be combined with other embodiments described herein, the mask includes a metal sheet, particularly a thin and/or flexible metal sheet. The metal material can be configured to be attracted by an electrostatic chuck.

As indicated by arrows 330, at least the mask 120 and the shutter 130 can be moved relative to the substrate carrier 20. According to some embodiments, which can be combined with other embodiments described herein, at least a portion of the mask module is movable relative to the substrate carrier. In particular, at least a portion of the mask module is movable relative to the substrate carrier for loading or unloading of a substrate. According to some embodiments, a portion of the mask module can be moved by the actuator 140. Additionally or alternatively, the mask module may include a further drive unit configured to move the mask module or a portion thereof relative to the carrier. While the shutter of the mask module may move in y-direction for selecting test elements or test element groups during the processing of a layer stack, a portion of the mask module, e.g. the mask and the shutter (and optionally the body of the mask module) may move at least in x-direction, and particularly also in z-direction for the loading and unloading of the substrate.

According to some embodiments, which can be combined with other embodiments described herein, the movement parallel to the plane of the substrate receiving surface allows for the unloading or loading of the substrate, for example, a glass plate. Specifically, the mask and the shutter can be moved to a loading position, in which the substrate receiving surface is not covered by the mask module, such that the substrate 10 can be loaded thereon or unloaded therefrom. The mask and the shutter can be moved to a deposition position, in which the mask and the shutter are at least partially arranged over the substrate 10 that is loaded and carried on the substrate receiving surface (see FIGS. 3A and 3B). Deposition of material(s) through the mask and shutter openings onto the substrate can be carried out in the deposition position.

According to some embodiments, which can be combined with other embodiments described herein, the movement perpendicular to the substrate receiving surface and/or the diagonal movement allows to separate the mask 120 from the substrate 10. Damage to the substrate can be avoided. According to some embodiments, which can be combined with other embodiments described herein, at least the mask and the shutter are movable relative to the substrate receiving surface in one or more of (i) a first moving direction perpendicular to the substrate receiving surface and a second direction parallel to the substrate receiving surface; (ii) a combined moving direction, being a combination of the first moving direction and the second moving direction (see tilted arrow in FIGS. 3A and 3B).

The mask and the shutter can be movable by the actuator 140 or a different driving unit. The actuators or driving units can be integrated in the mask module or may be separate. For example, the mask module can be coupled to a first edge region of the carrier or the carrier body and is movable between a first position, in which the mask is not arranged over the substrate receiving surface, and a second position (as shown in FIGS. 3A and 3B), in which the mask is arranged over an edge region of the substrate receiving surface. The mask module can be coupled to a first edge region of the carrier body, such that the mask can be positioned over a first edge region of the substrate receiving surface or the substrate, respectively.

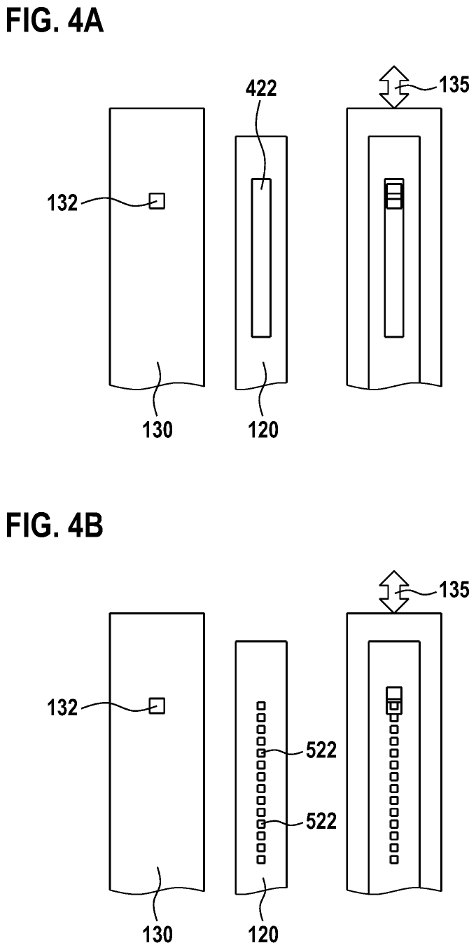

FIG. 4B shows the shutter 130 on the left-hand side having an opening, i.e. a second opening 132. Further openings can be provided as shown exemplarily in FIG. 1. A mask 120 having a plurality of openings 522 is shown in the center. The mask and the shutter on top of the mask is shown on the right-hand side in FIG. 4B. The shutter can be moved as indicated by arrow 135. Accordingly, the second opening 132 can be aligned with one of the first openings 522. Further, after movement of the shutter, the second opening 132 can be aligned with a different one of the first openings 522. Test elements or test element groups can be selected by movement of the shutter.

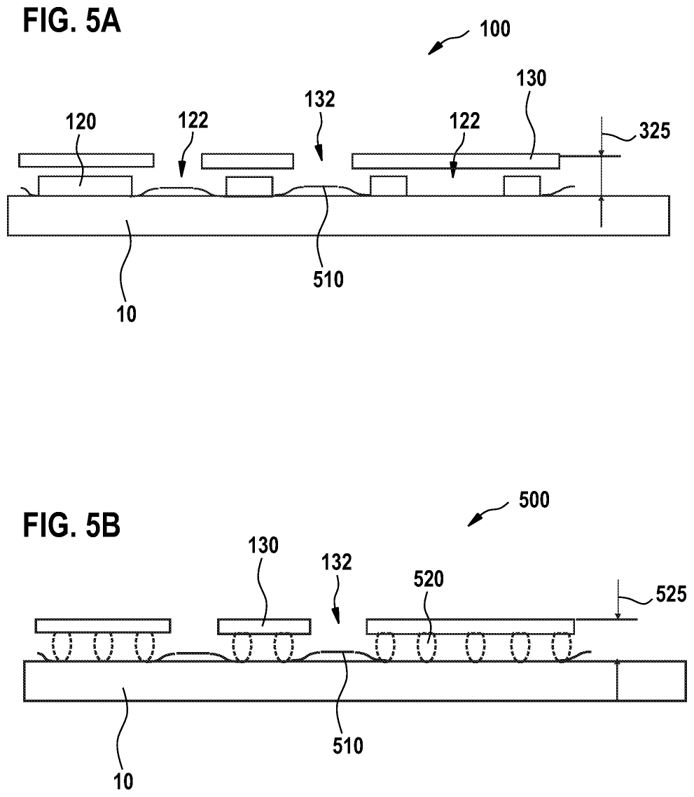

According to some embodiments, which can be combined with other embodiments described herein, the one or more first opening in the mask can be a plurality of first openings arranged as a line. The plurality of first opening can be equally spaced by a first distance and, in particularly, one or more second openings can be a plurality of second openings equally spaced by a second distance being N times the first distance, wherein N is an integer>1. As shown in FIG. 4B, the second opening 132 can be larger than each of the first openings 522. However, as will be explained in more detail with respect to FIG. 5A below, the second openings 132 can be smaller than the first openings. This may be beneficial to avoid or reduce deposition of material on the mask 120 in order to reduce particle generation, particularly upon movement of the shutter 130.

As shown on the right-hand side in FIG. 4B, the actuator is configured to move the movable shutter to position at least one of the one or more second openings 132 in alignment over at least one of the one or more first openings. Accordingly, the actuator can move the movable shutter to different monitoring positions including at least a first monitoring position and a second monitoring position, wherein in the first monitoring position, the one or more second openings are in alignment over a first subset or first sub-region of the one or more first openings, and in the second monitoring position, the one or more second openings are in alignment over a second subset or second sub-region of the one or more first openings different from the first subset or first sub-region.

Specifically, the one or more first openings can include a plurality of first openings, and in the first monitoring position, the one or more second openings are positioned in alignment over a first subset of the plurality of first openings, and in the second monitoring position, the one or more second openings are positioned in alignment over a second subset of the plurality of first openings, the second subset being different from the first subset.

For example, the one or more second openings can include N second openings and the plurality of first openings can include M subsets of N first openings, N and M being positive integers, the actuator being configured to move the movable shutter to M monitoring positions, and the N second openings being aligned over N first openings of a respective subset of first openings in each of the M monitoring positions. For example, N is two, three or more, and/or M is five, ten or more.

FIG. 4A shows a shutter 130 having a second opening 132 on the left-hand side and a mask 120 having a first opening 422 in the center. The first opening can be a slit opening. On the right-hand side in FIG. 4A, the shutter 130 is shown on top of the mask 120. According to some embodiments, the one or more first openings can be one or more slit openings forming a line. According to some implementations, the one or more second openings are smaller than each of the one or more slit openings. In a first monitoring position (shown in FIG. 4A), the one or more second openings are positioned in alignment over a first sub-region of the one or more slit openings, and in the second monitoring position (not shown), the one or more second openings are positioned in alignment over a second sub-region of the one or more slit openings different from the first sub-region. For example, the one or more first openings comprise N slit openings and the one or more second openings comprise N second openings, each of the N second openings being aligned above a sub-region of a respective one of the N slit openings in each of the different monitoring positions. For example, each of the N slit openings may include M sub-regions defining M monitoring positions, and each of the N second openings of the shutter may be aligned above a corresponding one of the M sub-regions of a respective one of the N slit openings in each of the M monitoring positions. In some embodiments, N can be two, three or more, and M can be five or more, or ten or more.

As described above, the one or more slit openings respectively have a slit length dimension in a length direction and a slit width dimension in a width direction smaller than the slit length dimension, and the one or more second openings of the movable shutter may have dimensions in the length direction and in the width direction smaller than the slit width dimension. Material deposition on the mask can be reduced or avoided if the one or more second openings of the movable shutter are smaller than the one or more first openings of the mask.

FIG. 5A shows a schematic side view of a mask module 100 provided over a portion of a substrate 10. The mask module includes a mask 120 and a shutter 130. The mask 120 includes a plurality of first opening 122. The shutter includes a plurality of second openings 132. A gap 325 can be provided between the substrate and the shutter 130. The second openings 132 can be positioned to be in alignment with respective first openings to allow for test material deposition on the substrate 10.

According to some embodiments, which can be combined with other embodiments described herein, one or more of the second openings 132, particularly each of the second openings 132, can be smaller than one or more of the first openings 122, particularly each of the first openings 122. As shown by the deposition profile 510, material is deposited on the substrate. Material deposition on the mask 120 can be reduced or avoided. Thus, no material is deposited between the mask 120 and the shutter 130, e.g. in a gap between the mask 120 and the shutter 130. Particle generation, particularly upon movement of the shutter 130 to align a second opening with a different first opening, can be reduced or avoided.

FIG. 5B shows a further embodiment of a mask module 500. The mask module 500 includes a shutter 130. The shutter can be moved, e.g. along an y-direction as described with respect to FIG. 2. One or more second openings 132 of the shutter can be positioned over a test element or test element group on the substrate 10. Distribution of test elements over the substrates allow for measuring or monitoring uniformity of material deposition. According to some embodiments, which can be combined with other embodiments described herein, one or more second openings in the shutter 130 of the mask module 500 can define a plurality of test elements or a test element group. Particularly, test elements distributed over the substrate, for example, along a line on the substrate, can define a test element group

A gap 525 is provided between the shutter 130 and the substrate 10. The gab avoids or reduces scratching of the shutter 130 over material deposited at a test element, as exemplarity shown by the deposition profile 510. Thus, particle generation is, particularly upon movement of the shutter 130 can be reduced or avoided. The gap 525 can be provided by one or more spacers 520. The one or more spacers 520 can be integrally formed with the shutter 130 or can be coupled to the shutter. The spacers shown in FIG. 5B are drawn with dotted lines. The dotted lines indicated the spacers are not in the paper plane shown in FIG. 5B. The spacers are provided in a plane, in which no second opening 132 is provided in the shutter. Accordingly, the spacers also do not generate particles upon movement of the shutter and particularly resulting movement of the spacers over the substrate 10.

According to one embodiment, a mask module configured to be coupled to a substrate carrier for carrying a substrate is provided. The mask module includes a body and a movable shutter, the movable shutter comprising one or more second openings. The mask module further includes one or more spacers arranged on a side of the movable shutter and configured to be provided between the movable shutter and the substrate and an actuator coupled to the movable shutter and configured to move the one or more second openings to align at least one opening of the one or more second openings over a test element on a substrate. For example, the one or more spacers can be coupled to the movable shutter or are integrally formed with the movable shutter.

According to some embodiments, which can be combined with other embodiments described herein, the one or more second openings of the shutter comprise two, three or more second openings distributed across the substrate receiving surface along a first direction, particularly wherein the first direction is a vertical direction. Particularly, the one or more second openings of the shutter comprise an upper opening arranged over an upper edge region of the substrate receiving surface, a lower opening arranged over a lower edge region of the substrate receiving surface, and, optionally, one or more further openings therebetween arranged over regions of the substrate receiving surface between the upper and the lower edge region. The thickness uniformity of the deposited material along the first direction can be inspected and/or monitored, if two, three or more second openings are provided distant from each other in the first direction, e.g. in the vertical direction.

In light of the above, multiple test element or test element group patterns can be provided by holes or slit holes. The mask, for example a thin mask stick, can be fixed to the mask module by welding or can be assembled on the module.

According to some embodiments, which can be combined with other embodiments described herein, multiple second openings can be provided in the shutter. The multiple second openings can provide a test element group. The holes, i.e. the second openings, can form an array defining the uniformity measurement points and positions, for example 3 points, such as top, middle and bottom.

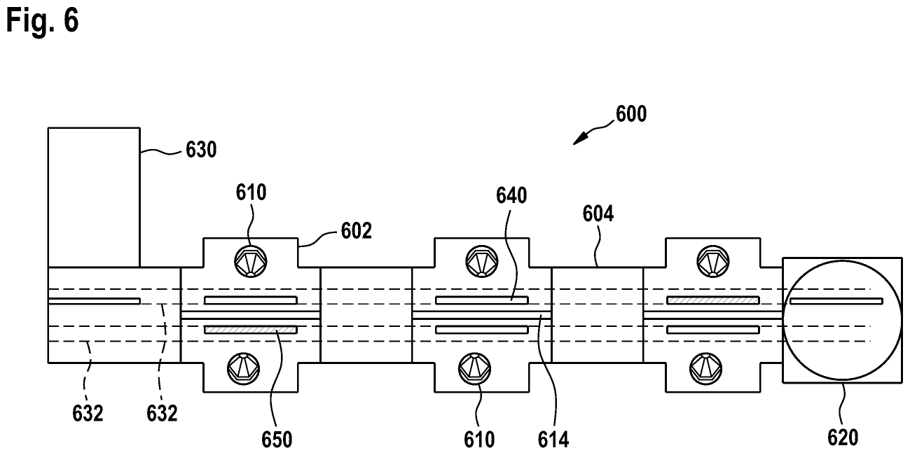

FIG. 6 shows a substrate processing system 600. The substrate processing system 600 shown in FIG. 6 includes a plurality of vacuum chambers. The one or more vacuum chambers can include a vacuum processing chamber 602 and a vacuum transfer chamber 604. FIG. 6 exemplarily shows three vacuum processing chambers and two vacuum transfer chambers. A vacuum processing chamber 602 is included in a substrate processing apparatus. A glass handling module 630 can be provided at one end of the substrate processing system 600. The glass handling module can load and/or unload substrates into the vacuum processing chamber, e.g. onto a respective substrate carrier. Further, a rotation module 620, for example, a vacuum rotation module, can be provided at a second end of the substrate processing system, which is distal to the mask handling module.

The substrate processing system as shown in FIG. 6 is an in-line substrate processing system. Substrates to be processed in the substrate processing system 600 are loaded at the glass handling module, for example, on substrate carriers, and are unloaded at the glass handling module, for example from substrate carriers. Substrates can be transported on the first substrate transportation track 632 in one direction, for example, from left to right in FIG. 1. The substrate can be rotated in a rotation module and transferred to a second substrate transportation track 632. The substrates can be transported, for example, from right to left, on the second substrate transportation track in order to be unloaded at the glass handling module. Accordingly, an empty carrier is provided, after unloading a processed substrate, at the same position at which a new substrate is to be loaded on the empty carrier. Thus, transportation of empty carriers, for example, on a carrier return path, can be avoided or reduced. Further, exposure of a carrier to an atmospheric condition can be avoided or reduced to a minimum. Further, the rotation module allows for “folding” the substrate processing system. As exemplarily shown in FIG. 6, the substrate processing system can include a forward transportation path on a first substrate transportation track for depositing a first group of material layers, for example organic layers, on the substrate and a backward transportation path on the second substrate transportation track for depositing a second group of material layers over the first group of material layers. The substrate is rotated between the forward transportation path and the backward transportation path by the rotation module 620. By “folding” the substrate processing system, the length of the substrate processing system can be reduced.

The in-line substrate processing system can be a display manufacturing system or a part of a display manufacturing system, in particular an OLED display manufacturing system, and more particularly an OLED display manufacturing system for large area substrates. The transport of a substrate carrier, i.e. the movement of a substrate carrier through the in-line substrate processing system can, for example, be carried out in a vertically orientated state of the substrate carrier. For example, substrate carriers can be configured to hold a substrate, such as a glass plate, in a vertically orientated state or a substantially vertically orientated state. The substrate can be a substrate carrier as described herein. Particularly, the substrate carrier can be a “normal substrate carrier” or “smart carrier” provided with a mask module as described herein.

In the example described above, the substrate processing system is described as a vertical substrate processing system, wherein the substrates are processed in a vertical orientation. However, the mask modules, substrate carriers, and substrate processing systems can also be provided as mask modules, substrate carriers, and substrate processing systems, wherein the substrates are processed in a horizontal orientation.

According to some embodiments, which can be combined with other embodiments described herein, the substrate carriers can be configured for holding or carrying the substrate or the substrate and a mask in a substantially vertical orientation. As used throughout the present disclosure, “vertical” or “substantially vertical” is understood, particularly when referring to the substrate orientation, to allow for a deviation from the vertical direction or orientation of ±20° or below, e.g. of ±10° or less. This deviation can be provided, for example, because a substrate support with some deviation from the vertical orientation might result in a more stable substrate position. Further, fewer particles reach the substrate surface when the substrate is tilted forward. However, the substrate orientation, e.g., during the deposition of materials, such as organic or metallic materials, on a substrate in a high vacuum, is considered as substantially vertical, which is considered different from the horizontal substrate orientation, which may be considered as horizontal ±20° or less.

As shown in FIG. 6, a substrate transportation track 632 can be provided. According to some embodiments, a substrate transportation track can be configured for contactless transportation of a substrate carrier. The contactless transportation may be a magnetic levitation system. In particular, the magnetic levitation system may be provided so that at least a part of the weight of a substrate carrier is carried by the magnetic levitation system. The carriers can then be guided essentially contactlessly along a substrate transportation track through the in-line substrate processing system. In particular, the transportation may include a carrier holding structure and carrier driving structure. A carrier holding structure can be configured for a contactless holding of a carrier. A carrier driving structure can be configured for a contactless translation of a carrier. A carrier holding structure may include a magnetic levitation system for contactless holding of a substrate carrier. Further, a carrier driving structure may include a magnetic drive system for a contactless driving of a carrier.

A substrate processing system can include a forward transportation path. The forward transportation path includes a substrate transportation track. For example, the forward transportation path may be the upper transportation paths in FIG. 6, wherein a substrate is transported from left to right through the substrate processing system 600. Deposition sources 610 can be provided in the vacuum processing system. According to some embodiments, which can be combined with other embodiments described herein, a deposition source 610 can be an organic deposition source. Additionally, a deposition source can be a metal deposition source, for example, to deposit a cathode of the device to be manufactured on the substrate.

The deposition source is provided in vacuum processing chambers of the substrate processing apparatus. According to some embodiments, which can be combined with other embodiments described herein, the one or more deposition sources in the substrate processing system 600 can be evaporation sources, and can particularly be line sources extending essentially vertically. Organic material or a metal-containing material can be deposited on a substrate, for example, while the substrate moves past a deposition source 610 providing a line source.

According to some embodiments, which can be combined with other embodiments described herein, the forward transportation path and the backward transportation path can be separated by means of one or more protection shields 614. The protection shields 614 separate the forward transportation path from the backward transportation path to allow for, for example, the deposition of different materials in a vacuum processing chamber of the substrate processing system 600.

As shown in FIG. 6, a plurality of substrate carriers is provided in the substrate processing system 600. For example, during mass manufacturing, a “normal substrate carrier” 640 can be replaced by a “smart carrier” 650. FIG. 6 shows “normal substrate carriers” in white color and “smart carriers” in black color. Due to the compatible design of the carriers and/or the attachability of the mask module onto a carrier, the benefits of a “smart carrier” according to embodiments of the present disclosure can be provided for mass production, i.e. during normal operation.

Reverting to FIGS. 3A and 3B, at least a portion of the mask module has been described as being movable for loading or unloading a substrate, for example, a glass plate. Loading and unloading can be provided in a horizontal substrate orientation, e.g. the substrate facing upwards. Accordingly, the glass (or substrate) can also be exchanged on a “smart carrier” under vacuum, particularly by moving the mask and the shutter off the substrate receiving surface. Further, a “smart carrier” can be stocked in a mask stocker, or a mask module may be attached or detached in a mask stocker.

According to some embodiments, which can be combined with other embodiments described herein, the mask module may also be attachable or detachable for cleaning, particularly for cleaning the shutter and/or the mask.

As shown in FIG. 6, a “smart carrier” can move through the substrate processing system. The shutter can be in a first monitoring position while the substrate carrier moves the substrate past the first deposition source 610. A shutter moving signal can be provided at, before or after a specific deposition source, for example, a specific process chamber. For example, a shutter moving signal can be provided by remote control or a mechanical signal. Accordingly, the shutter can be moved from the first monitoring position to a second monitoring position different from the first monitoring position. In the first monitoring position, the shutter exposes a first test element or a first test element group, i.e. one or more first openings in the mask. In the second monitoring position, the shutter exposes a second test element or a second test element group, i.e. one or more different first openings in the mask. Accordingly, the material deposition from the first deposition source can be separated from the material deposition from another deposition source. Material properties or material layer properties, such as layer thickness and/or thickness uniformity of a layer across the substrate surface, can be measured, for example, with conventional measurement techniques, in order to measure and/or monitor material properties or material layer properties.

According to some embodiments, which can be combined with other embodiments described herein, a substrate carrier can be an electrostatic chuck (E-chuck) providing an electrostatic force for holding the substrate and optionally the mask at the substrate carrier, and particularly at the substrate receiving surface. For example, the substrate carrier includes an electrode arrangement configured to provide an attracting force acting on the substrate.

The embodiments described herein can be utilized for the deposition of materials, such as organic or metallic materials, on large area substrates, e.g. for OLED display manufacturing. Specifically, the substrates, for which the structures and methods according to embodiments described herein are provided, may be large area substrates. For instance, a large area substrate can be GEN 4.5, which corresponds to a surface area of about 0.67 m² (0.73 m×0.92 m), GEN 5, which corresponds to a surface area of about 1.4 m² (1.1 m×1.3 m), GEN 7.5, which corresponds to a surface area of about 4.29 m² (1.95 m×2.2 m), GEN 8.5, which corresponds to a surface area of about 5.7 m² (2.2 m×2.5 m), or even GEN 10, which corresponds to a surface area of about 8.7 m² (2.85 m×3.05 m). Even larger generations such as GEN 11 and GEN 12 and corresponding surface areas can similarly be implemented. Half sizes of the GEN generations may also be provided in OLED display manufacturing.

According to some embodiments, which can be combined with other embodiments described herein, the substrate thickness can be from 0.1 to 1.8 mm. The substrate thickness can be about 0.9 mm or less, such as 0.5 mm. The term “substrate” as used herein may particularly embrace substantially inflexible substrates, e.g. a glass plate or other substrates. However, the present disclosure is not limited thereto and the term “substrate” may also embrace flexible substrates such as a web or a foil. The term “substantially inflexible” is understood to distinguish over “flexible”. Specifically, a substantially inflexible substrate can have a certain degree of flexibility, e.g. a glass plate having a thickness of 0.9 mm or less, such as 0.5 mm or less, wherein the flexibility of the substantially inflexible substrate is small in comparison to the flexible substrates.

Embodiments of the present disclosure provide a carrier and/or mask module for a carrier for layer thickness measurements and/or layer uniformity measurements, or the like, particularly on different material layers deposited by more than one deposition source, particularly a plurality of deposition sources. A transfer carrier, i.e. a substrate carrier, for layer thickness measurements in an evaporation device is provided. The carrier according to embodiments of the present disclosure, which can be combined with other embodiments described herein, can include a substrate chucking unit, particularly an electrostatic chuck. In some embodiments, the carrier can be operated in both horizontal and vertical systems. Due to the detachable concept for the mask module and/or capability to move at least a portion of the mask module, the glass can be loaded or unloaded from the glass loading/unloading module. An inspection process of individual material layers or individual materials can be provided without removing the glass from the vacuum chamber. By having a wireless control system, the condition of the carrier can be checked in real time.

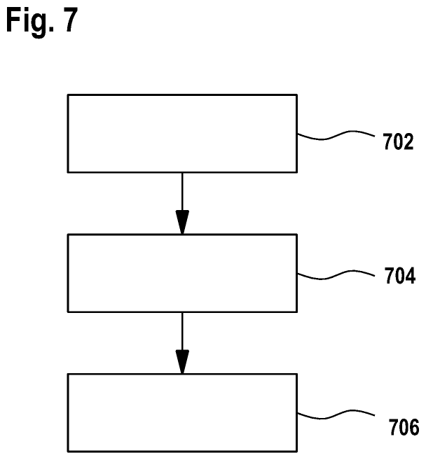

FIG. 7 shows a flow chart illustrating one or more method of processing a substrate. At operation 702, a first material layer is deposited on the substrate. The first material is deposited in a device region and a first test region of a plurality of test regions. The first material is deposited in the first test region through one or more first openings in a mask and through one or more second openings in a movable shutter. At operation 704, the one or more second openings are moved relative to the one or more first openings. For example, the movable shutter can be moved by an actuator. Particularly, the movable shutter can be moved in y-direction as shown in FIGS. 1 and 2. At operation 706, a second material layer is deposited on the substrate. The second material is deposited in the device region and a second test region of the plurality of test regions. The second material is deposited in the second test region through one or more first openings in the mask and through one or more second openings in the movable shutter. Particularly, the one or more first openings for depositing the second material are openings different from the one or more first openings for depositing the first material.

According to some embodiments, which can be combined with other embodiments described herein, the movable shutter can be moved with an actuator to different monitoring positions or test regions, including at least a first monitoring position or first test region and a second monitoring position or second test region. In the first monitoring position, the one or more second openings are in alignment over a first subset or first sub-region of the one or more first openings, and in the second monitoring position, the one or more second openings are in alignment over a second subset or second sub-region of the one or more first openings different from the first subset or first sub-region. Different materials are deposited in individual test regions of the plurality of test regions, i.e. different monitoring positions.

According to some embodiments, which can be combined with other embodiments described herein, a common test region or common monitoring position can be provided, wherein two or more materials are deposited in the common test region.

According to some embodiments, the method may further include that before depositing the first material layer, a substrate is loaded on the substrate carrier. Thereafter, the mask and the movable shutter are moved relative to a carrier body of a substrate carrier, e.g. in x-direction and z-direction shown in FIGS. 3A and 3B, to provide the mask and the movable shutter above the substrate. The substrate is fixed onto the substrate carrier using a force of an electrostatic chuck. Further, the mask can be fixed onto the substrate carrier with a force of the electrostatic chuck. Methods as described herein may include the embodiments of a mask module and a substrate carrier according to any of the embodiments of the present disclosure. Operations to implement, utilize or operate the mask module or substrate carrier can be provided in methods described herein.

According to further embodiments, the methods of processing a substrate as described herein can be provided for methods for manufacturing layer stacks of devices, particularly OLED display devices.

In light of the above, one or more of the following advantages can be provided by embodiments of the present disclosure. Material properties and material layer properties can be individually monitored. For example, a layer thickness of an individual layer can be determined. Deposition source conditions can be individually monitored. A substrate carrier can be modified to be a “smart carrier”. A “smart carrier” can be utilized during mass production to evaluate the manufacturing conditions during normal operation of a substrate processing system.

While the foregoing is directed to some embodiments, other and further embodiments may be devised without departing from the scope, the scope being determined by the claims that follow.

1. A mask module configured to be coupled to a substrate carrier; comprising:
a body;
a mask coupled to the body, the mask comprising one or more first openings;
a movable shutter, the movable shutter comprising one or more second openings; and
an actuator coupled to the movable shutter and configured to move the one or more second openings to align at least one opening of the one or more second openings over at least one opening of the one or more first openings.

2. The mask module according to claim 1, wherein the mask module is detachable from and attachable to the substrate carrier.

3. The mask module according to claim 1, wherein at least a portion of the mask module is movable relative to the substrate carrier.

4. The mask module according to claim 1, wherein the mask module further comprising an actuator configured to move at least a portion of the mask module relative to the carrier.

5. The mask module according to claim 1, wherein the mask includes a mask stick or mask stripe.

6. The mask module according to claim 1, wherein the mask includes a metal sheet.

7. The mask module according to claim 1, wherein the one or more first openings are a plurality of first openings arranged to form a line.

8. The mask module according to claim 7, wherein the plurality of first opening is equally spaced by a first distance.

9. The mask module according to claim 1, wherein the one or more second openings are smaller than each of the one or more first openings.

10. A mask module configured to be coupled to a substrate carrier for carrying a substrate; comprising:
a body;
a movable shutter, the movable shutter comprising one or more second openings;
one or more spacers arranged on a side of the movable shutter and configured to be provided between the movable shutter and the substrate; and
an actuator coupled to the movable shutter and configured to move the one or more second openings to align at least one opening of the one or more second openings over a test element on the substrate.

11. The mask module according to claim 10, wherein the one or more spacers are coupled to the movable shutter or are integrally formed with the movable shutter.

12. A substrate carrier; comprising:
a carrier body;
an electrostatic chuck;
a substrate receiving surface; and a mask module configured to be coupled to a substrate carrier, comprising:
a body;
a mask coupled to the body, the mask comprising one or more first openings;
a movable shutter, the movable shutter comprising one or more second openings; and
an actuator coupled to the movable shutter and configured to move the one or more second openings to align at least one opening of the one or more second openings over at least one opening of the one or more first openings.

13. The substrate carrier according to claim 12; wherein at least the mask and the shutter are movable relative to the substrate receiving surface in:
(i) a first moving direction perpendicular to the substrate receiving surface and a second direction parallel to the substrate receiving surface;
(ii) a combined moving direction being a combination of the first moving direction and the second moving direction; or
(iii) the first moving direction, the second moving direction, and the combined moving direction.

14. The substrate carrier according to claim 12, wherein at least the mask and the shutter are movable by a driving unit or by the actuator.

15. The substrate carrier according to claim 12, wherein the movable shutter is movable parallel to the substrate receiving surface.

16. The substrate carrier according to claim 12, wherein the actuator is configured to move the movable shutter to position at least one of the one or more second openings in alignment over at least one of the one or more first openings.

17. The substrate carrier according to claim 12, wherein the actuator is configured to move the movable shutter to different monitoring positions including at least a first monitoring position and a second monitoring position,
wherein, in the first monitoring position, the one or more second openings are in alignment over a first subset or first sub-region of the one or more first openings, and, in the second monitoring position, the one or more second openings are in alignment over a second subset or second sub-region of the one or more first openings different from the first subset or first sub-region.

18. A substrate processing system, comprising:
one or more vacuum chambers; a plurality of deposition source provided in the one or more vacuum chambers; a substrate transportation track configured to move a substrate of a plurality of substrates subsequently past the plurality of deposition source for depositing layers of different materials on the substrate; and one or more substrate carriers, comprising
a carrier body:
an electrostatic chuck;
a substrate receiving surface; and
a mask module configured to be coupled to a substrate carrier;
comprising:
a body:
a mask coupled to the body, the mask comprising one or more first openings;
a movable shutter, the movable shutter comprising one or more second openings; and
an actuator coupled to the movable shutter and configured to move the one or more second openings to align at least one opening of the one or more second openings over at least one opening of the one or more first openings.

19. A method of processing a substrate; comprising:
depositing a first material layer on the substrate, the first material being deposited in a device region and a first test region of a plurality of test regions, wherein the first material is deposited in the first test region through one or more first openings in a mask and through one or more second openings in a movable shutter; moving the one or more second openings relative to the one or more first openings; and depositing a second material layer on the substrate, the second material being deposited in the device region and a second test region of the plurality of test regions, wherein the second material is deposited in the second test region through one or more first openings in the mask and through one or more second openings in the movable shutter.

20. The method of claim 19, wherein moving the one or more second openings comprises:
moving the movable shutter with an actuator to different monitoring positions including at least a first monitoring position and a second monitoring position,
wherein, in the first monitoring position, the one or more second openings are in alignment over a first subset or first sub-region of the one or more first openings, and in the second monitoring position, the one or more second openings are in alignment over a second subset or second sub-region of the one or more first openings different from the first subset or first sub-region.
